(19) United States
(12) Patent Application Publication
(10) Pub. No.: US 2006/0044751 A1
(43) Pub. Date: Mar. 2, 2006

(54) Computer enclosure incorporating a touchpad with a selective button set

(75) Inventors: Wen-Tang Peng, Tu-Cheng (TW); Guang-Yi Zhang, Shenzhen (CN); Wei-Ming Yu, Shenzhen (CN); Shao-Kun Chen, Shenzhen (CN); Zhe Zhang, Shenzhen (CN); Jiang-Ping Zhu, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/018,079

(22) Filed: Dec. 20, 2004

(30) Foreign Application Priority Data
Aug. 27, 2004 (CN) 200420083517.3

(51) Int. Cl. G06F 1/16; H05K 5/00

(52) U.S. Cl. 361/686

(57) ABSTRACT

A computer enclosure includes a base (50), and a top cover (30) attached to the base. A selective button set (10) is disposed atop the top cover, and two protrusions (11) are extended downward from the selective button set. A pair of apertures (331) is defined in the top cover, for receiving the protrusions of the selective button set respectively. A touchpad (31) is attached on the top cover to cooperate with the selective button set to control cursor movement.

### BACKGROUND OF THE INVENTION

1. Field of the Invention

The present invention relates to a computer enclosure, and more particularly to a computer enclosure which incorporates a touchpad with a selective button set.

2. Description of the Related Art

Varieties of cursor control devices, such as touchpad, track ball, joystick, etc. has been widely used in portable computers to control cursor movement on displays. The cursor control devices are typically used in cooperation with a selective button set having two selective buttons which function as left and right buttons of a mouse respectively. The selective button set is typically attached to inner surface of a computer enclosure of a portable computer.

As described in U.S. Pat. No. 6,177,924, a selective button set is attached to inner surface of a computer enclosure. A pair of button holes is defined in the computer enclosure for exposing the selective buttons of the selective button set. Size of each button hole is required to be fit to size of corresponding selective button. However, strength of the computer enclosure will be badly impaired due to the button holes in the computer enclosure. Furthermore, dirt and humidity will easily enter the computer enclosure via the button holes.

### SUMMARY OF THE INVENTION

Accordingly, an object of the present invention is to provide a computer enclosure which has least impairment of strength when introducing a selective button set.

Another object of the present invention is to provide a computer enclosure which has good resistance to dirt and humidity.

To achieve the above objects, a computer enclosure in accordance with the present invention comprises a base, and a top cover attached to the base. A selective button set is disposed atop the top cover, and two protrusions are extended downward from the selective button set. A pair of apertures is defined in the top cover, for receiving the protrusions of the selective button set respectively. A touchpad is attached on the top cover to cooperate with the selective button set to control cursor movement.

Other objects, advantages and novel features of the present invention will be drawn from the following detailed description of a preferred embodiment of the present invention with the attached drawings, in which:

### BRIEF DESCRIPTION OF THE DRAWINGS

FIG. 1 is an exploded, isometric view of a selective button set and a top cover in accordance with a preferred embodiment of the present invention;

FIG. 2 is an enlarged isometric view of the selective button set of FIG. 1, but viewed from another aspect;

FIG. 3 is an enlarged isometric view of the top cover of FIG. 1, but viewed from another aspect;

FIG. 4 is an assembled view of FIG. 1, but viewed from another aspect; and

FIG. 5 is an isometric view of a computer enclosure incorporating a touchpad with the selective button set.

### DETAILED DESCRIPTION OF THE PRESENT INVENTION

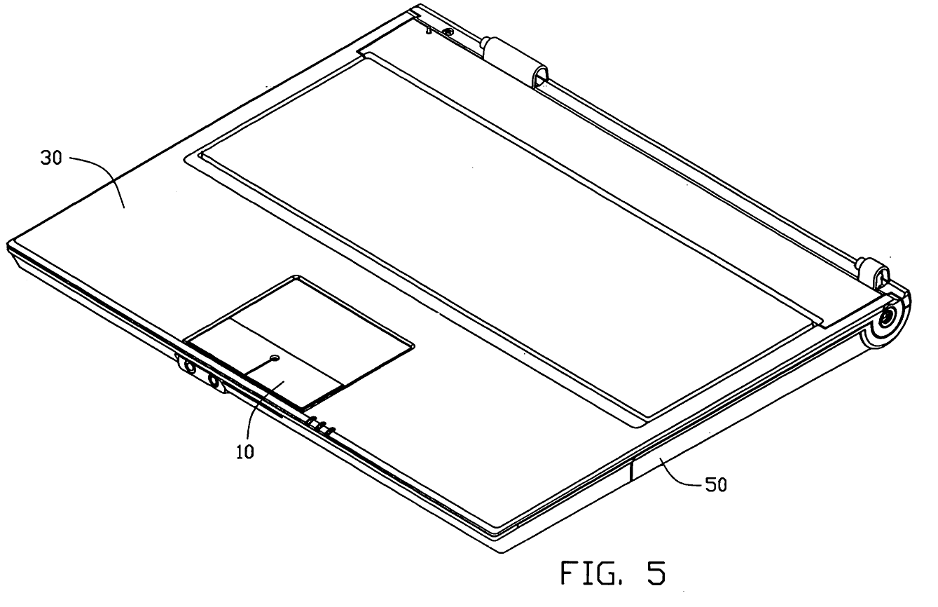

Referring to FIG. 5, an enclosure of an electronic device like a computer in accordance with a preferred embodiment of the present invention comprises a base 50 having a top cover 30, and a selective button set 10 attached to the top cover 30.

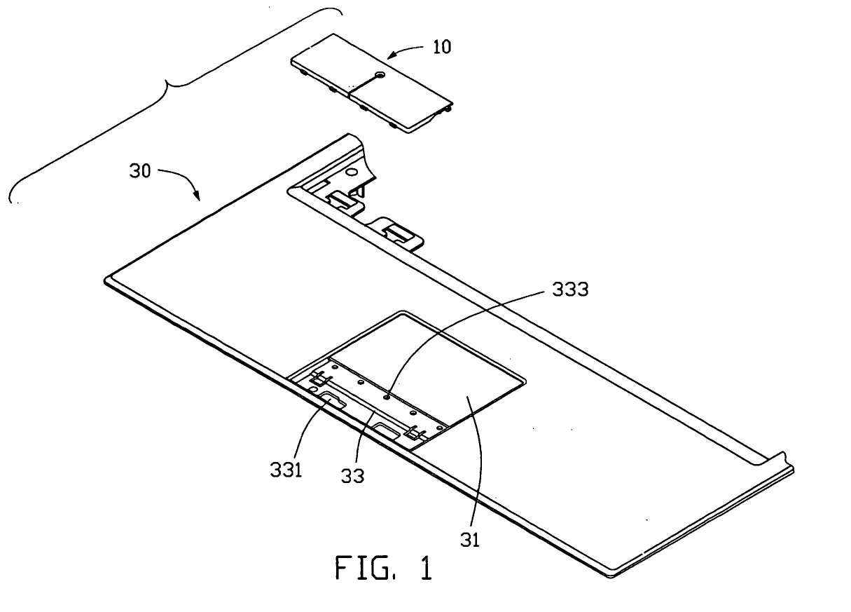

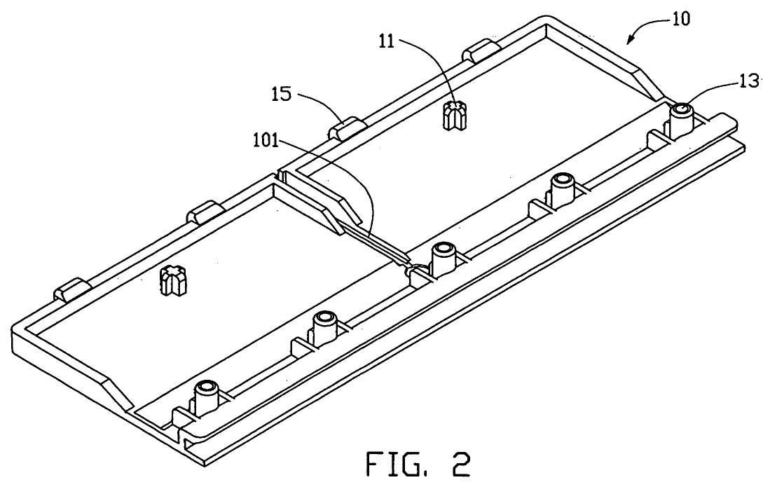

Referring to FIGS. 1 through 3, the selective button set 10 is formed of a plastic material, and is partially divided into two integral elastic selective buttons by a slit 101. The two selective buttons function as left and right buttons of a mouse respectively. A pair of protrusions 11 depends from bottom surfaces of the two selective buttons respectively, for actuating corresponding switches (not shown) disposed in the base 50 to produce electronic signals. A plurality of posts 13 depends from a rear edge portion of the selective button set 10. A pair of tabs 15 is extended downward from a front edge of each selective button.

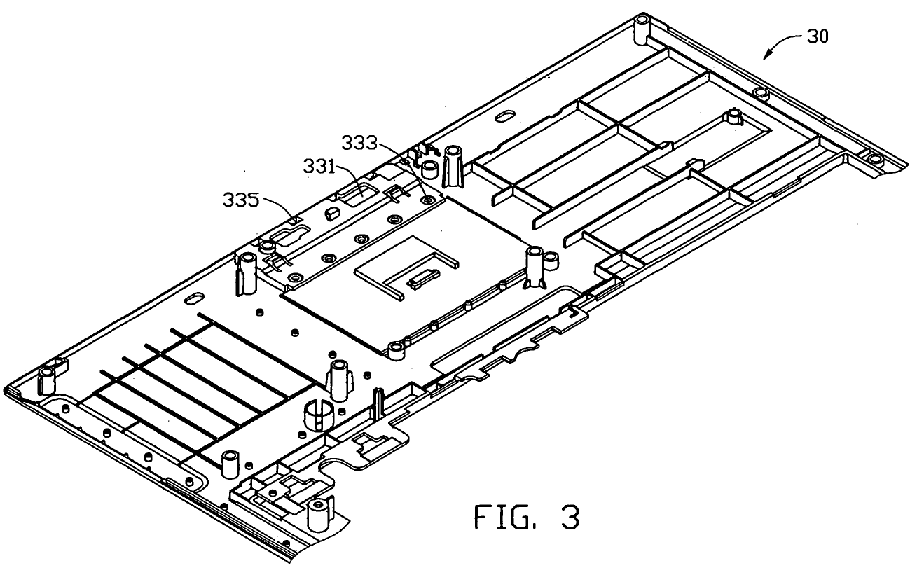

A touchpad 31 is positioned on a front portion of the top cover 30. A concave portion 33 is defined in a top surface of the top cover 30 at front of the touchpad 31, for receiving the selective button set 10 in a space defined aside via an aperture of the space facing upwards. A pair of apertures 331 is defined in a front edge section of the concave portion 33, corresponding to the protrusions 11 of the selective button set 10 respectively. A plurality of through holes 333 is defined in the concave portion 33 adjacent the touchpad 31. Four slots 335 are defined in the concave portion 33 at front of the apertures 331 adjoining a front edge of the concave portion 33 (see FIG. 3).

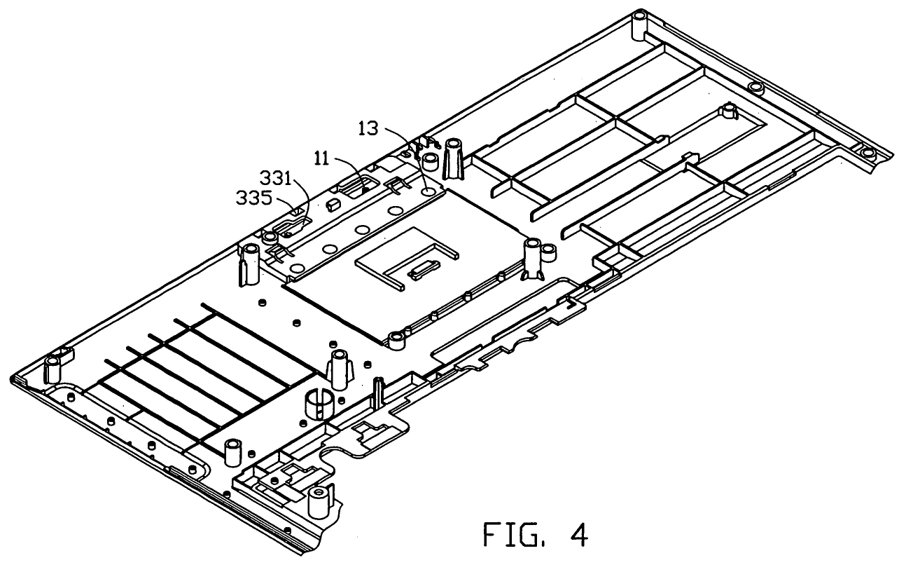

Referring to FIG. 4, in assembly, the selective button set 10 is placed in the concave portion 33 of the top cover 30, the protrusions 11 of the selective button set 10 is extended into the base 50 through the apertures 331 of the top cover 30. The posts 13 of the selective button set 10 are extended through the holes 333 of the top cover 30 respectively. The tabs 15 are received in the slots 335 of the top cover 30. Free ends of the posts 13 are then heated to solder with a bottom surface of the top cover 30. The selective button set 10 is thus attached to the top cover 30. The top cover 30 is finally attached to the base 50 (see FIG. 5).

In the present invention, the apertures 331, size of which corresponds to size of the protrusions 11 rather than size of the selective buttons of the selective button set 10, are defined in the top cover 30, so strength of the top cover 30 is least impaired, and it is difficult for dirt and humidity to enter the base 50 via the apertures 331.

It is understood that the invention may be embodied in other forms without departing from the spirit thereof. Thus, the present example and embodiment are to be considered in all respects as illustrative and not restrictive, and the invention is not to be limited to the details given herein.

What is claimed is:

1. A computer enclosure comprising:
a base;
a top cover attached to the base, a pair of apertures defined in the top cover;
a selective button set disposed atop the top cover, two protrusions extended downward from the selective button set through the apertures of the top cover respectively for being manipulated to produce electronic signals; and
a touchpad attached on the top cover to cooperate with the selective button set.

2. The computer enclosure as claimed in claim 1, wherein the selective button set is partially divided by a slit to form two elastic buttons, and the protrusions depend from the buttons respectively.

3. The computer enclosure as claimed in claim 2, wherein a concave portion is defined in the top cover, and the selective button set is defined in the concave portion.

4. The computer enclosure as claimed in claim 3, wherein a plurality of holes is defined in the concave portion of the top cover, and a plurality of posts is formed on a rear edge portion of the selective button set to engage in the holes of the top cover.

5. The computer enclosure as claimed in claim 4, wherein a plurality of tabs is formed on a front edge of the selective button set, and a plurality of slots is defined in the concave portion of the top cover to receive the tabs respectively.

6. The computer enclosure as claimed in claim 1, wherein the selective button set is formed of a plastic material.

7. An assembly comprising:
a base with a detachable top cover, the top cover incorporating a cursor control device, a pair of apertures defined in the top cover; and
a selective button set comprising two selective buttons functioning as left and right buttons of a typical mouse, two protrusions depending from the selective buttons respectively corresponding to the apertures of the top cover;
wherein the apertures of the top cover are defined to allow passing of the corresponding protrusions of the selective buttons and disallow passing of the selective buttons.

8. The assembly as claimed in claim 7, wherein the cursor control device is a touchpad.

9. The assembly as claimed in claim 7, wherein a plurality of posts is formed on the selective button set, a plurality of holes is defined in the top cover receiving the posts of the selective button set respectively, and the posts are heated to solder the selective button set to the top cover.

10. A button assembly for an electronic device, comprising:
a concave portion formed on an enclosure of said electronic device and defining a space neighboring said concave portion, said space communicating with outside of said enclosure via a first aperture at a side opposing to said concave portion and with inside of said enclosure via a second aperture at said concave, said first aperture sized larger than said second aperture; and
a button set sized substantially same as said first aperture and receivable in said space via said first aperture so as to be movable in said space for performing a predetermined control function of said electronic device.

11. The button assembly as claimed in claim 10, wherein a plurality of tabs is formed around said button set and receivable in corresponding slots around said concave portion for preventing said button set from leaving said space after installation thereof.

12. The button assembly as claimed in claim 10, wherein a plurality of posts extend from said button set toward said concave portion of said enclosure and protrusive in corresponding holes of said concave portion so as to allow said plurality of posts fixable to said concave portion in order for limiting movement of said button set in said space.

13. The button assembly as claimed in claim 10, wherein said enclosure comprises a touchpad formed neighboring said concave portion.
